(19) United States
(12) Patent Application Publication
(10) Pub. No.: US 2007/0117367 A1
(43) Pub. Date: May 24, 2007

(54) FLUID INJECTION APPARATUS AND FABRICATION METHOD THEREOF

(75) Inventors: Der Rong Shyn, Hsinchu County (TW); Wei Lin Chen, Taipei (TW); Fan Chung Tseng, Hsinchu City (TW); Wen Pin Chuang, Kaohsiung County (TW); Guang Ren Shen, Yulin County (TW)

Correspondence Address: QUINTERO LAW OFFICE, PC, 2210 MAIN STREET, SUITE 200, SANTA MONICA, CA, 90405, US

(73) Assignee: BENQ CORPORATION, TAOYUAN (TW)

(21) Appl. No.: 11/562,376

(22) Filed: Nov. 21, 2006

(30) Foreign Application Priority Data
Nov. 23, 2005 (TW) 94141099

(51) Int. Cl. H01L 21/336; H01L 21/44

(52) U.S. Cl. 438/597; 438/264

(57) ABSTRACT

A fluid injection apparatus is disclosed. A chamber wall is disposed overlying the substrate to define an area. A nozzle plate comprising a nozzle is disposed overlying the chamber wall to form a chamber on the area, wherein the chamber wall and the nozzle plate are integrated into a structure layer. A manifold is disposed in the substrate, communicated with the chamber.

### BACKGROUND OF THE INVENTION

1. Field of the Invention

The present invention relates to a fluid injection apparatus and fabrication methods thereof, and in particular relates to a micro fluid injection apparatus and fabrication methods thereof.

2. Description of the Related Art

Micro fluid injection apparatuses have been widely used in digital apparatuses, such as inkjet printers or others. With development of micro system engineering, micro fluid injection apparatuses are further used in other applications, such as fuel injection systems, cell sorting, drug delivery systems, print lithography or micro jet propulsion systems.

FIGS. 1A˜1C show a conventional monolithic fabrication of a fluid injection apparatus 100. Referring to FIG. 1A, a substrate 102 is provided, and a patterned sacrificial layer 104 is formed on a first side 101 thereof. Next, a structure layer 106 is formed to cover the sacrificial layer 104 and the first side 101 of the substrate 102. A mask layer 108 is formed on a second side 103 of the substrate 102. Referring to FIG. 1B, the substrate 102 is etched using the patterned mask layer 108 as a mask to form a manifold 110, in which the sacrificial layer 104 is exposed. Thereafter, the sacrificial layer 104 is etched through the manifold 110 to form a chamber 112. Due to the characteristics of dielectric material, the sacrificial layer 104 formed of dielectric materials is unable to achieve sufficient thickness. Consequently, as shown in FIG. 1C, a further silicon etching process step is required to enlarge the chamber 112′.

In addition, the sacrificial layer 104 formed of dielectric material is typically formed by chemical vapor deposition, which as a higher cost, and further requires an additional silicon etching process step to enlarge the chamber 112′ which also increases fabrication cost and duration. Further, undercutting may occur when the chamber is enlarged by etching the silicon substrate 102. Thus, the size of the chamber 112′ is not easily controlled.

### BRIEF SUMMARY OF INVENTION

A detailed description is given in the following embodiments with reference to the accompanying drawings. These and other problems are generally solved or circumvented, and technical advantages are generally achieved, by preferred illustrative embodiments of the present invention, which provide a fluid injection apparatus.

The invention provides a fluid injection apparatus. A chamber wall is disposed overlying the substrate to define an area. A nozzle plate comprising a nozzle is disposed overlying the chamber wall to form a chamber in the area, wherein the chamber wall and the nozzle plate are integrated into a structure layer. A manifold is disposed in the substrate, communicated with the chamber.

The invention further provides a method for forming a fluid injection apparatus. A patterned sacrificial layer is formed on the substrate. An electroplate seed layer is formed at least covering the patterned sacrificial layer. A structure layer is electroplated on the electroplate seed layer. The structure layer is patterned to form a nozzle. A portion of the electroplate seed layer within the nozzle is removed. The sacrificial layer is removed to form a chamber. A side of the substrate opposite to the side where the structure layer is disposed is patterned to form a manifold, communicated with the chamber.

The invention provides a method for forming a fluid injection apparatus. A polymer sacrificial layer is formed on a portion of the substrate. An isolation layer is formed at least covering the polymer sacrificial layer. A polymer structure layer is formed at least covering the isolation layer. The polymer structure layer is patterned to form a nozzle. A portion of the isolation layer within the nozzle is removed. The polymer sacrificial layer is removed to form a chamber. A side of the substrate opposite to the side is patterned where the structure layer is disposed to form a manifold, communicated with the chamber.

### BRIEF DESCRIPTION OF DRAWINGS

The present invention can be more fully understood by reading the subsequent detailed description and examples with references made to the accompanying drawings, wherein:

FIG. 1A˜1C shows a conventional monolithic fabrication of a fluid injection apparatus.

FIG. 2A˜FIG. 2F show intermediate cross sections of a fluid injection apparatus of an embodiment of the invention.

FIG. 3A˜FIG. 3F show intermediate cross sections of a fluid injection apparatus of an embodiment of the invention.

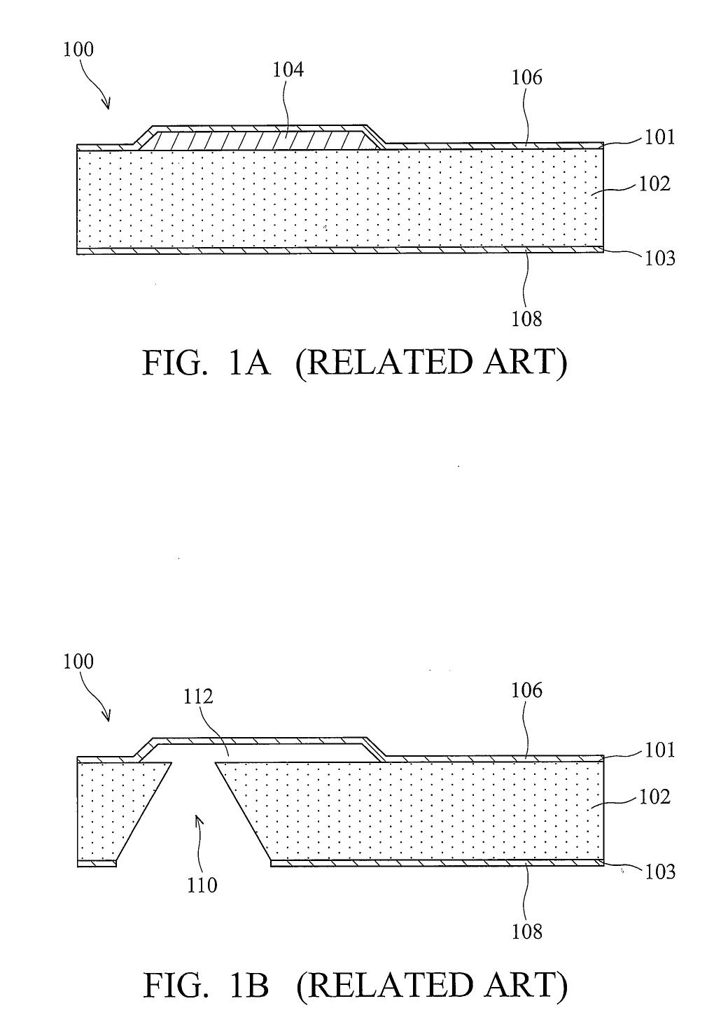

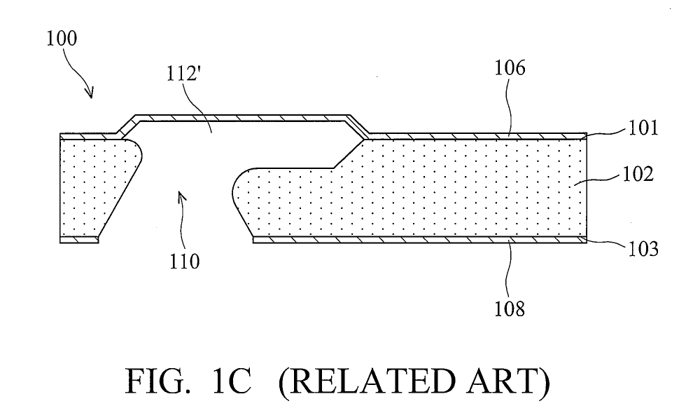

### DETAILED DESCRIPTION OF INVENTION

The following description is of the best-contemplated mode of carrying out the invention. This description is made for the purpose of illustrating the general principles of the invention and should not be taken in a limiting sense. The scope of the invention is best determined by reference to the appended claims. Embodiments of the invention, which provides a fluid injection apparatus, will be described in greater detail by referring to the drawings that accompany the invention. It is noted that in the accompanying drawings, like and/or corresponding elements are referred to by like reference numerals. The invention is not limited to any particular fluid driving device or driving method, which is not particularly mentioned in the specification. Any fluid driving device or driving method, such as thermal bubble driven or piezoelectric actuator can be applied to the invention.

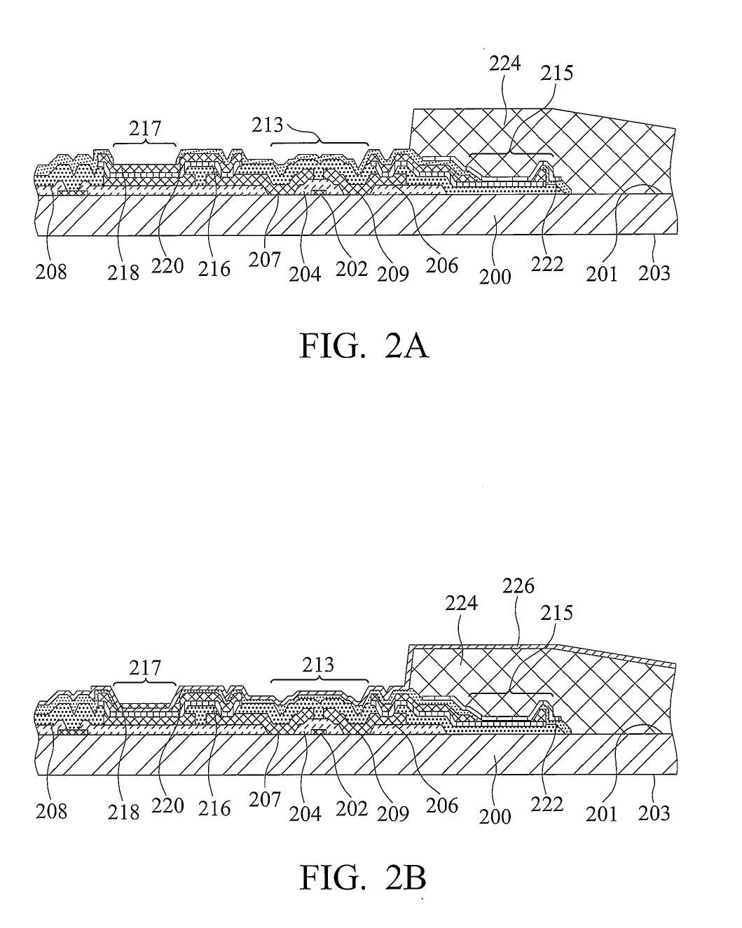

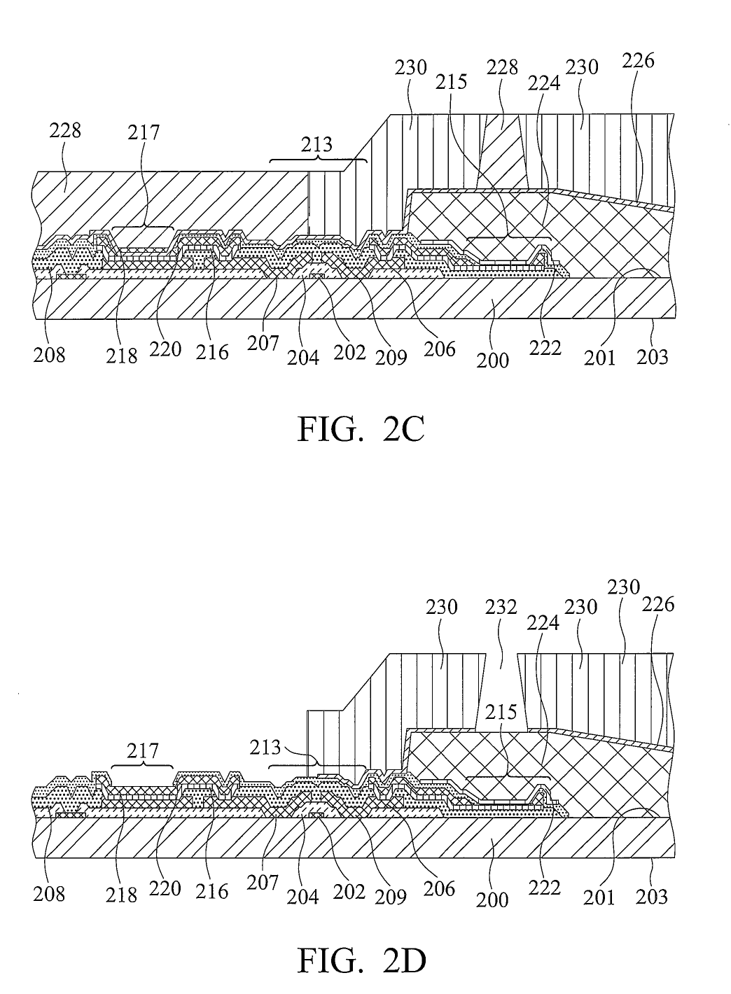

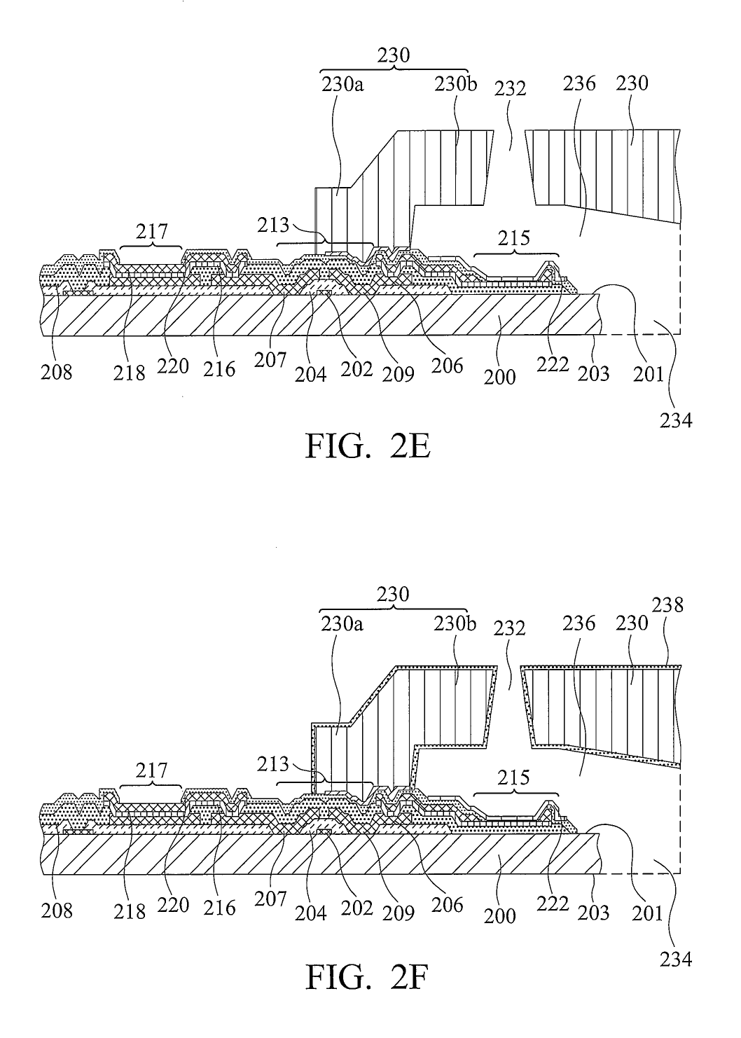

FIG. 2A˜FIG. 2F show intermediate cross sections of a fluid injection apparatus of an embodiment of the invention. Referring to FIG. 2A, a substrate 200, such as silicon substrate or glass substrate, is provided. Preferably, the substrate 200 is a silicon substrate. A gate 202, for example comprising polysilicon or metal, is formed on the substrate 200. Next, a first dielectric layer 204, such as silicon oxide, silicon nitride or silicon oxynitride, is formed to cover the gate 202 and a portion of the substrate 200. A first conductive layer 206, such as Al or Cu, is formed on the first dielectric layer 204 and a portion of the substrate 200, wherein portions of the first conductive layer 206 on opposite sides of the gate 202 acts a source 207 and a drain 209. The gate 202 and related elements thereof constitute a fluid control device 213 of an embodiment of the invention.

Thereafter, a second dielectric layer 208, such as silicon oxide, silicon nitride or silicon oxynitride, is formed on a portion of the first conductive layer 206, the first dielectric layer 204 and the substrate 200. It is noticed that the second dielectric layer 208 exposes a portion of the first conductive layer 206 and the drain 209 to form a via. A electric resistance layer 216 is formed to cover a portion of the first conductive layer 206 and the source 207. Next, a second conductive layer 218, such as Al or Cu, is formed on the electric resistance layer 216, wherein the second conductive layer 218 directly contacts the electric resistance layer 216. The second conductive layer 218 and the electric resistance layer 216 are patterned by, for example lithography and etching. Next, a portion of the second conductive layer 218 overlying the heating device area is etched to expose a portion of the electric resistance layer 216. Thus, the electric resistance layer 216 and the first conductive layer 206 thereunder constitute a heating device 215. A passivation layer 220, such as SiC or SiN, is formed on the second conductive layer 218 and the electric resistance layer 216, and a metal protective layer 222, such as Ta, is formed on a portion of the electric resistance layer 216 overlying the heating device 215. Thereafter, the passivation layer 222 is patterned to form a contact pad 217.

Next, a sacrificial layer 224 is formed on the first side 201 of the substrate 200 by, for example deposition or coating, and then patterned by lithography and etching. In an embodiment of the invention, the fluid controlling device 213 is disposed on the first side. In this embodiment, the sacrificial layer 224 can comprise dielectric materials, such as an oxide, or a macromolecular compound, such as a resist. In a preferred embodiment of the invention, the thickness of the sacrificial layer 224 can be about 5 μm˜100 μm.

Referring to FIG. 2B, a electroplate seed layer 226 is formed on the passivation layer 220 and the sacrificial layer 224 by, for example plasma vapor deposition. Preferably, the electroplate seed layer 226 comprises a Ti layer and an Au layer on the Ti layer. The Ti layer, preferably has a thickness of less than about 1000 Å, is for increasing adhesion. The Au layer, preferably has a thickness of about 1000 Å˜8000 Å, is for electroplate seeding. Alternatively, in another embodiment of the invention, the electroplate seed layer 226 comprises a Ti layer and an Ni layer on the Ti layer.

Referring to FIG. 2C, a patterned resist layer 228 is formed on a portion of the electroplate seed layer 226 predetermined to form a nozzle, and the pad 217.

Next, a structure layer 230, for example comprising Au, is formed on the electroplate seed layer 226 by, for example an electroplating process, wherein the portion of the electroplate seed layer 226 covered by the resist layer 228 is not reacted in the electroplating solution during the electroplating process. Thus, the structure layer 230 is formed on a portion of the electroplate seed layer 226 uncovered by the resist layer 228. The structure layer 230 can have a thickness of about 5 μm˜100 μm. Referring to FIG. 2D, the resist layer 228 is removed by, for example development, stripper or plasma ashing. Subsequent to removal of the resist layer 228, a nozzle 232 in the structure layer 226 is formed. Next, a portion of the electroplate seed layer 226 within the nozzle 232 is removed by, for example etching. It is noticed that formation of the nozzle 232 is not limited to the described method. The nozzle 232 can also be form by patterning the structure layer 230 with lithography and etching.

Referring to FIG. 2E, the second side 203 of the substrate 200 is patterned by, for example, lithography and etching, or sand blasting to form a manifold 234, wherein the sacrificial layer 224 is exposed. Next, the sacrificial layer 224 is removed through the manifold 234 by, for example etching, to form a chamber 236 connected to the manifold 234. When the sacrificial layer 234 is formed of macromolecular compound, it can be removed by plasma ashing or stripper. The invention, however, is not limited thereto. The sacrificial layer 234 can be removed through the nozzle 232. Next, the manifold 234 is formed in the substrate 200. It is noticed that the structure layer 230 comprises a sidewall portion 230a and a nozzle plate portion 230b on the sidewall portion 230a. In the preferred embodiment of the invention, since the structure layer 230 is formed by electroplating, the sidewall portion 230a and a nozzle plate portion 230b are formed as a whole. The entire structure layer 230 is formed as a whole. The chamber wall 230a and the nozzle plate 230b are integrated into a structure layer.

Next, the electroplate seed layer 226 in the chamber 236 and neighboring the structure layer 230 is removed by isotropic etching, such as wet etching. Referring to FIG. 2F, a structure protective layer 238, such as Au with thickness of about 3000 Å˜8000 Å thick, is formed to cover the structure layer 230. Preferably, the structure protective layer 238 is formed by electroless plating, in which the structure protective layer 238 can selectively cover the structure layer 230. In this embodiment of the invention, since the structure layer 230, comprising the sidewalls and the nozzle plate, is formed as a whole, the structure layer could be more rigid. In addition, due to formation of the nozzle 232 by a monolithic process, a distance between the nozzle 232 and the heater 215 could be precisely controlled.

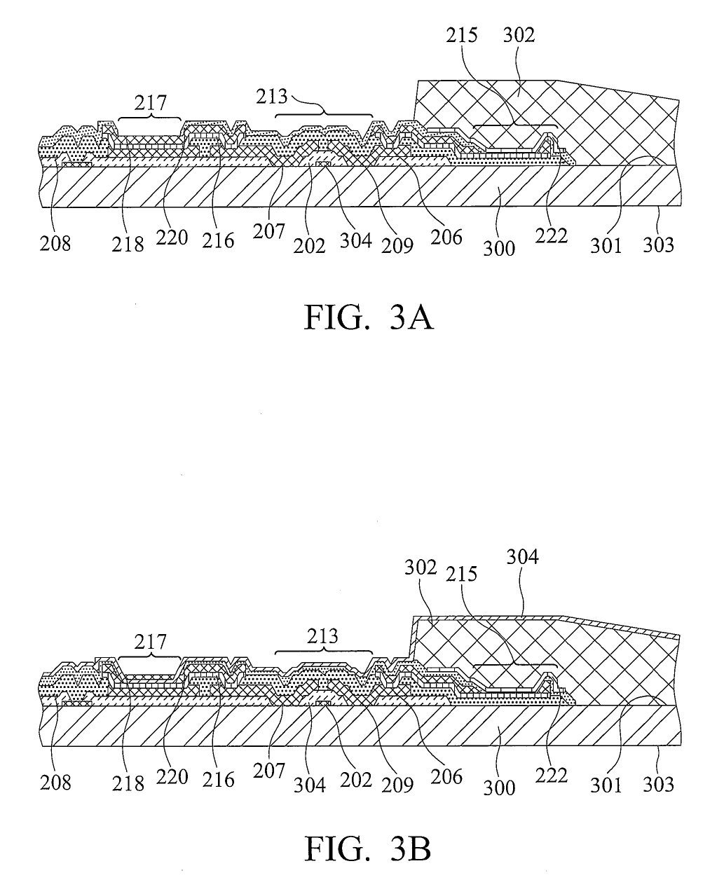

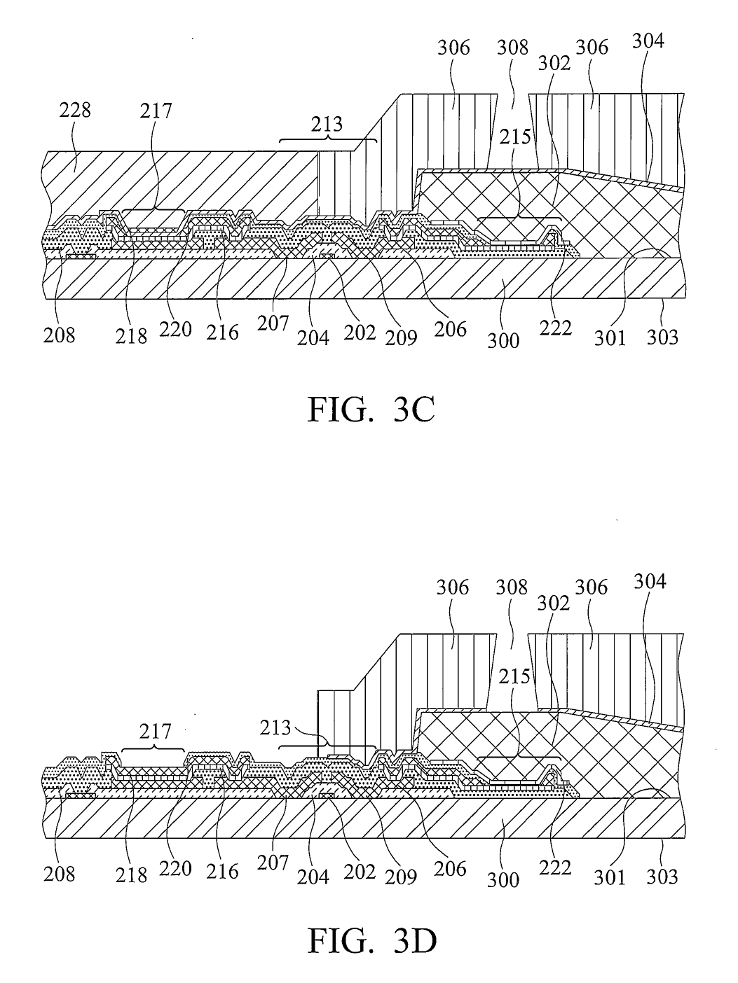

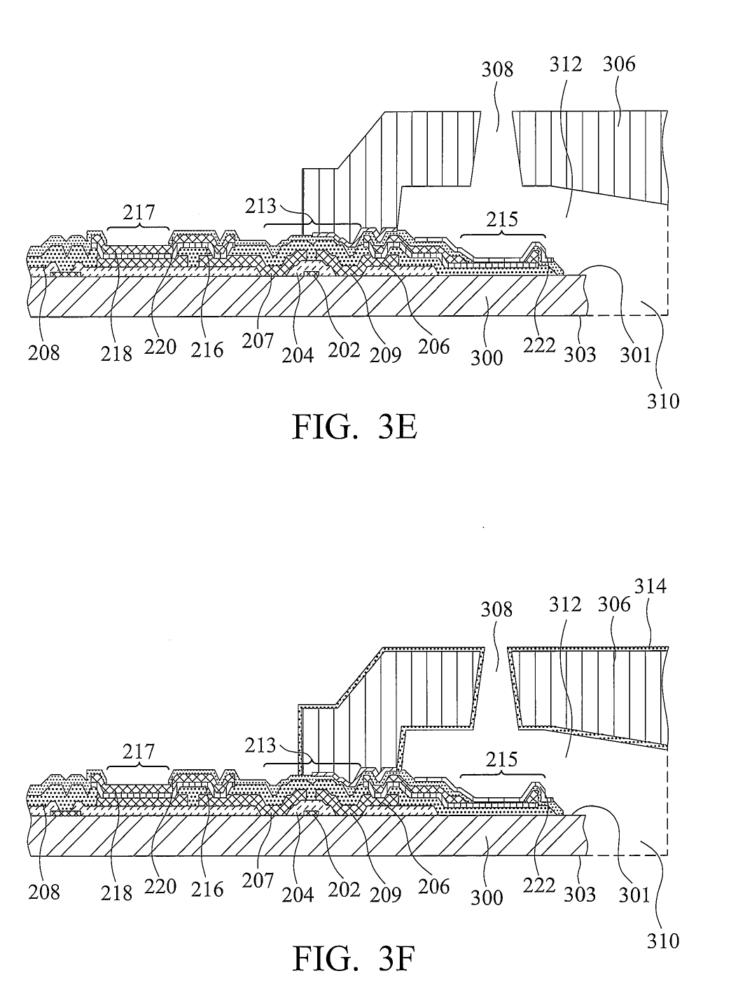

FIG. 3A˜FIG. 3F show intermediate cross sections of a fluid injection apparatus of an embodiment of the invention. Referring to FIG. 3A, a substrate 300, such as silicon substrate or glass substrate, is provided. Preferably, the substrate 300 is a silicon substrate. A gate 202, for example comprising polysilicon or metal, is formed on the substrate 300. Next, a first dielectric layer 204, such as silicon oxide, silicon nitride or silicon oxynitride, is formed to cover the gate 202 and a portion of the substrate 300. A first conductive layer 206, such as Al or Cu, is formed on the first dielectric layer 204 and a portion of the substrate 300, wherein portions of the first conductive layer 206 on opposite sides of the gate 202 acts a source 207 and a drain 209. The gate 202 and related elements thereof constitute a fluid control device 213 of an embodiment of the invention.

Thereafter, a second dielectric layer 208, such as silicon oxide, silicon nitride or silicon oxynitride, is formed on a portion of the first conductive layer 206, the first dielectric layer 204 and the substrate 300. It is noticed that the second dielectric layer 208 exposes a portion of the first conductive layer 206 and the drain 209 to form a via. An electric resistance layer 216 is formed to cover a portion of the first conductive layer 206 and the source 207. Next, a second conductive layer 218, such as Al or Cu, is formed on the electric resistance layer 216, wherein the second conductive layer 218 directly contacts the electric resistance layer 216. The second conductive layer 218 and the electric resistance layer 216 are patterned by, for example lithography and etching. Next, a portion of the second conductive layer 218 overlying the heating device area is etched to expose a portion of the electric resistance layer 216. Thus, the electric resistance layer 216 and the first conductive layer 206 thereunder constitute a heating device 215. A passivation layer 220, such as SiC or SiN, is formed on the second conductive layer 218 and the electric resistance layer 216. A metal protective layer 222, such as Ta, is formed on a portion of the electric resistance layer 216 overlying the heating device 215. Thereafter, the passivation layer 222 is patterned to form a contact pad 217.

Next, a polymer sacrificial layer 302 is formed on the first side 301 of the substrate 300 by, for example deposition or coating, and then patterned by lithography and etching. In an embodiment of the invention, the fluid controlling device 213 is disposed on the first side 301 of the substrate. The polymer sacrificial layer 302 can comprise light sensitive materials, such as photoresist, or non light sensitive materials. Thickness of the polymer sacrificial layer 302 can be about 5 μm˜100 μm. Preferably, the thickness of the polymer sacrificial layer 302 is more than about 10 μm, thus, a chamber defined by the polymer sacrificial layer 302 has sufficient volume.

Referring to FIG. 3B, an isolation layer 304 is formed on the passivation layer 220 and the polymer sacrificial layer 302 by, for example plasma vapor deposition. The isolation layer 304 can be macromolecular compound or metal. Preferably, the isolation layer 304 is Ti and more preferably is about 1500 Å˜2500 Å thick. In this embodiment, the isolation layer 304 is for preventing the polymer sacrificial layer 304 from reaction with a polymer structure layer formed in following steps.

Next, referring to FIG. 3C, a polymer structure layer 306 is formed to cover the isolation layer 304 by, for example coating, and lithography and etching thereafter, and the polymer structure layer are then patterned to form a nozzle 308. The polymer structure layer 306 can comprise light sensitive materials, such as photoresist, or non light sensitive materials. Referring to FIG. 3D, a portion of the isolation layer 304 within the nozzle 308 is removed through the nozzle 308.

In another embodiment of the invention, the polymer sacrificial layer 302 and the polymer structure layer 306 are formed of different high macromolecular materials. The polymer sacrificial layer 302 and the polymer structure layer 306 can contact directly without the isolation layer 304 therebetween when suitable materials are chosen for the polymer sacrificial layer 302 and the polymer structure layer 306 to not react with each other.

Referring to FIG. 3E, the second side 303 of the substrate 300 is patterned by, for example lithography and etching, or sand blasting to form a manifold 310, wherein the polymer sacrificial layer 302 is exposed. Next, the polymer sacrificial layer 302 is removed through the manifold 310 by, for example etching, to form a chamber 312 connected to the manifold 310. In this embodiment of the invention, the polymer sacrificial layer 302 can be removed by plasma ashing or stripper. The invention, however, is not limited thereto. The polymer sacrificial layer 302 can also be removed through the nozzle 308. Next, the manifold 310 is formed in the substrate 300. It is noticed that the isolation layer 304 can be used as an etching stop when the polymer sacrificial layer 302 is etched. Due to the difference in etching selectivity between the polymer sacrificial layer 302 and the isolation layer 304, etching of the polymer sacrificial layer 302 can be stopped at the isolation layer 304, thus, the polymer sacrificial layer 302 should not be over etched. In addition, since the polymer sacrificial layer 302 is a macromolecular compound, it can be removed by solvent. Thus, process steps for forming the fluid injection apparatus could be simpler, and cost could be reduced. Next, the isolation layer 304 in the chamber 312 and neighboring the structure layer 306 is removed by isotropic etching, such as wet etching.

Referring to FIG. 3F, a structure protective layer 314, such as Ni with a thickness of about 3000˜8000 Å, is formed to cover the structure layer 306. In this embodiment of the invention, due to the characteristics of the polymer sacrificial layer 302, the polymer sacrificial layer 302 can achieve a thickness of more than about 10 μm. Thus, the chamber 312 can have sufficient volume, and enlargement of the chamber 312 could be eliminated. Consequently, cost and process duration is reduced. In addition, undercutting generated during chamber enlargement could be eliminated, and chamber size can be controlled more precisely.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A fluid injection apparatus, comprising:
a substrate;
a chamber wall disposed overlying the substrate to define an area;
a nozzle plate comprising a nozzle, disposed overlying the chamber wall to form a chamber on the area, wherein the chamber wall and the nozzle plate are integrated into a structure layer; and
a manifold in the substrate, communicated with the chamber.

2. The fluid injection apparatus as claimed in claim 1, wherein the structure layer is metal.

3. The fluid injection apparatus as claimed in claim 1, wherein the structure layer is macromolecular compound.

4. The fluid injection apparatus as claimed in claim 3, wherein the macromolecular compound is photoresist or polymer.

5. A method for forming a fluid injection apparatus, comprising:
providing a substrate;
forming a patterned sacrificial layer on the substrate;
forming an electroplate seed layer, at least covering the patterned sacrificial layer;
electroplating a structure layer on the electroplate seed layer;
patterning the structure layer to form a nozzle;
removing a portion of the electroplate seed layer within the nozzle;
removing the sacrificial layer to form a chamber; and
patterning the substrate to form a manifold, communicated with the chamber.

6. The method for forming a fluid injection apparatus as claimed in claim 5, wherein the patterned sacrificial layer is macromolecular compound.

7. The method for forming a fluid injection apparatus as claimed in claim 5, wherein the patterned sacrificial layer comprises dielectric materials.

8. The method for forming a fluid injection apparatus as claimed in claim 5, wherein the step of electroplating a structure layer on the electroplate seed layer, and patterning the structure layer to form a nozzle comprise:
forming a patterned resist layer on a portion of the substrate and the electroplate seed layer;
forming the structure layer on a portion of the electroplate seed layer uncovered by the patterned resist layer by electroplating; and
removing the patterned resist layer to form the nozzle.

9. The method for forming a fluid injection apparatus as claimed in claim 5, further comprising forming a structure protective layer to cover the structure layer.

10. The method for forming a fluid injection apparatus as claimed in claim 5, wherein the electroplate seed layer comprises a Ti layer and an Au layer overlying the Ti layer.

11. The method for forming a fluid injection apparatus as claimed in claim 5, wherein the electroplate seed layer comprises a Ti layer and a Ni layer overlying the Ti layer.

12. A method for forming a fluid injection apparatus, comprising:
providing a substrate;
forming a polymer sacrificial layer on a portion of the substrate;
forming an isolation layer, at least covering the polymer sacrificial layer;
forming a polymer structure layer, at least covering the isolation layer;
patterning the polymer structure layer to form a nozzle;
removing a portion of the isolation layer within the nozzle;
removing the polymer sacrificial layer to form a chamber; and
patterning the substrate to form a manifold, communicated with the chamber.

13. The method for forming a fluid injection apparatus as claimed in claim 12, wherein the polymer sacrificial layer is photoresist or polymer.

14. The method for forming a fluid injection apparatus as claimed in claim 12, wherein the polymer sacrificial layer is about 5 μm˜100 μm thick.

15. The method for forming a fluid injection apparatus as claimed in claim 12, wherein a thickness of the polymer sacrificial layer is substantially more than 10 μm.

16. The method for forming a fluid injection apparatus as claimed in claim 12, wherein the polymer structure layer is photoresist or polymer.

17. The method for forming a fluid injection apparatus as claimed in claim 12, wherein the polymer structure layer is about 5 μm˜100 μm thick.

18. The method for forming a fluid injection apparatus as claimed in claim 12, wherein the isolation layer is metal or polymer.

19. The method for forming a fluid injection apparatus as claimed in claim 12, wherein the step of removing the polymer sacrificial layer is accomplished by plasma ashing or stripper.

20. The method for forming a fluid injection apparatus as claimed in claim 12, wherein the polymer structure layer comprises photo sensitive materials.

21. The method for forming a fluid injection apparatus as claimed in claim 12, wherein the polymer structure layer comprises non-photo sensitive materials.
